(19) United States
(12) Patent Application Publication
(10) Pub. No.: US 2016/0268098 A1
(43) Pub. Date: Sep. 15, 2016

(54) SCANNING ELECTRON MICROSCOPE CAPABLE OF CONTROLLING BEAM SPOT AND MEASUREMENT METHOD USING THE SAME

(71) Applicant: AUROS TECHNOLOGY CO., LTD., Hwaseong-si Gyeonggi-do (KR)

(72) Inventors: JONG LIP CHOI, FREMONT, CA (US); SANG MYEONG LEE, HWASEONG-SI, GYEONGGI-DO (KR); HO YOUNG HEO, HWASEONG-SI, GYEONGGI-DO (KR); YUN GI LEE, HWASEONG-SI, GYEONGGI-DO (KR); SEUNG CHUL OH, HWASEONG-SI, GYEONGGI-DO (KR)

(21) Appl. No.: 14/404,442

(22) PCT Filed: Jun. 12, 2014
(86) PCT No.: PCT/KR2014/005142

§ 371 Date: Nov. 26, 2014

(30) Foreign Application Priority Data
Aug. 8, 2013 (KR) 10-2013-0094300

(51) Int. Cl. H01J 37/28; H01J 37/141

(52) U.S. Cl. CPC H01J 37/28; H01J 37/141; H01J 2237/1405; H01J 2237/2817; H01J 2237/04922

(57) ABSTRACT

A scanning electron microscope capable of controlling the spot of an electron beam and a measurement method using the same. The scanning electron microscope includes electron magnets disposed in a path in which an electron beam irradiated to a sample moves from the electron beam source of the scanning electron microscope to a sample and configured to control and irradiate the spot of the electron beam in a linear electron beam having a different horizontal to vertical ratio. A control unit controls a ratio and direction of the spot of the electron beam by controlling a supply voltage of the electron magnets.

### BACKGROUND OF THE INVENTION

1. Technical Field

The present invention relates to a scanning electron microscope (SEM) capable of controlling the spot of an electron beam and, more particularly, to a scanning electron microscope capable of controlling the spot of an electron beam, which can further improve the functionality of measurement by controlling and irradiating the spot of the electron beam of the scanning electron microscope.

2. Description of the Related Art

A semiconductor device is a device realized by the human's memory, recording ability through electronic means and is used as a storage medium in a computer, a communication device, a broadcasting device, and education and entertainment devices. The semiconductor device was placed on the market in 1971. At that time, a memory capacity was 1 KB. Thereafter, the memory capacity of the semiconductor device is extraordinarily increased, for example, quadrupled in 2˜3 years.

As the memory capacity of the semiconductor device is increased, the size of a pattern is reduced and the uniformity of a pattern shape is much lowered. Accordingly, an electron microscope is used in order to check the shape of a pattern formed in the semiconductor device.

The electron microscope is divided into a transmission electron microscope and a scanning electron microscope. The transmission electron microscope is equipment for monitoring the density and thickness of a sample and information within an element. The scanning electron microscope is equipment for monitoring information about a surface of a sample. Recently, the scanning electron microscope is chiefly used due to a simple structure and a low price.

The scanning electron microscope irradiates an electron beam to a subject to be tested using a predose function and collects secondary electrons, emitted from the subject to be tested, in a data form.

Furthermore, in the amount of detected secondary electrons with respect to the aspect ratio of a pattern, a high aspect ratio rather than a difference in the amount of secondary electrons emitted by a beam irradiated to the pattern affects a low angle of reflection attributable to an energy level of the secondary electrons.

As a result, in a surface test of a subject to be tested using the scanning electron microscope, if patterns P1 to P4 formed in a wafer have different aspect ratios (refer to FIGS. 1a and 1b) and different shapes and are made of different materials, accurate monitoring is difficult because electrons are differently charged by a beam. If electrons are charged based on the pattern P2 having the greatest aspect ratio, electrons are excessively charged in the pattern P1 having a small aspect ratio, thereby making measurement impossible or making the pattern P1 collapse. If electrons are charged based on the pattern P1 having a small aspect ratio, electrons are not sufficiently charged in the pattern P2 having a great aspect ratio. Furthermore, a surface test is difficult due to a low angle of reflection attributable to a low energy level although electrons are charged in the pattern P2.

Meanwhile, the spot of the electron beam of a conventional scanning electron microscope is used to test a subject to be tested using a circular spot of several microns in size. Such a measurement method using an extreme circle has slow speed and a low degree of precision.

### SUMMARY OF THE INVENTION

Accordingly, the present invention has been made keeping in mind the above problems occurring in the prior art, and an object of the present invention is provide a scanning electron microscope capable of controlling the spot of an electron beam, which is capable of improving the degree of accuracy and precision and capable of high-speed measurement by controlling the shape of a measurement electron beam in order to provide a scanning electron microscope capable of resolution accuracy, measurement precision, and high-speed scanning when measuring a surface shape using the scanning electron microscope.

In accordance with an aspect of the present invention, there is provided a scanning electron microscope (SEM) including electron magnets disposed in a path in which an electron beam irradiated to a sample moves from the electron beam source of the scanning electron microscope to a sample and configured to control and irradiate the spot of the electron beam in a linear electron beam having a different horizontal to vertical ratio. When the electron beam is output by the electron beam source, a control unit controls the ratio and direction of the spot of the electron beam by controlling the supply voltage of the electron magnets.

In accordance with another aspect of the present invention, there is provided a measurement method using a scanning electron microscope including electron magnets disposed in a path in which an electron beam irradiated to a sample moves from the electron beam source of the scanning electron microscope to a sample and configured to control and irradiate the spot of the electron beam in a linear electron beam having a different horizontal to vertical ratio. The measurement method includes consecutively irradiating and scanning, by a control unit, a linear electron beam by controlling the supply voltage of the electron magnets when the electron beam is output by the electron beam source.

Furthermore, the electron beam includes all the spot sizes of an electron beam that is first determined in controlling the spot of the electron beam using the electron magnets. Controlling the spot of the electron beam includes controlling the spot of the electron beam using the electron magnets when the size of the spot is 2.0 nm in a normal state and controlling the spot of the electron beam using the electron magnets when the size of the spot is less than 2.0 nm or 2.0 nm or more.

In accordance with yet another aspect of the present invention, there is provided a scanning electron microscope configured to control a path in which the spot of an electron beam reaches a sample, including an electromagnetic lens including an electron gun for outputting an electron beam and an electron coil, a pair of stigmators, and electron magnets placed on a side opposite a side in which the spot of the electron beam is controlled by the pair of stigmators and configured to control or correct the spot in a desired shape. The electron magnets are disposed in a path in which the electron beam irradiated to a sample moves from an electron beam source of the scanning electron microscope to a sample and configured to control and irradiate the spot of the electron beam in a linear electron beam having a different horizontal to vertical ratio. When the electron beam is output by the electron beam source, a control unit controls the ratio and direction of the spot of the electron beam by controlling a supply voltage of the electron magnets.

### BRIEF DESCRIPTION OF THE DRAWINGS

FIGS. 1a and 1b are diagrams illustrating a wafer including patterns;

FIG. 2 is a diagram illustrating the spot shape of the electron beam of a conventional scanning electron microscope;

FIG. 3 illustrates the configuration of a scanning electron microscope capable of controlling the spot of an electron beam in accordance with an embodiment of the present invention;

FIG. 4 is a diagram illustrating the shapes of electron beams formed by the scanning electron microscope capable of controlling the spot of an electron beam in accordance with an embodiment of the present invention; and

FIG. 5 is a diagram consecutively illustrating the scanning states of electron beams through the scanning electron microscope in accordance with an embodiment of the present invention.

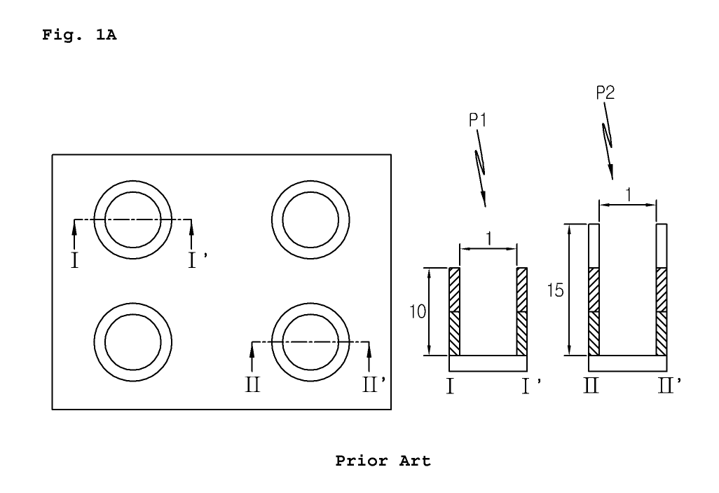

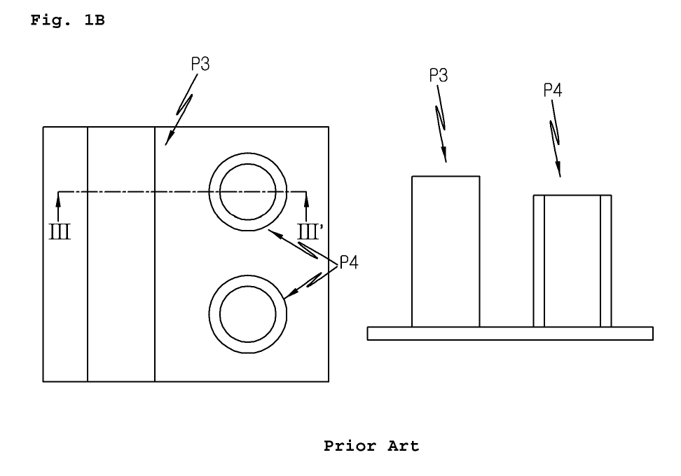

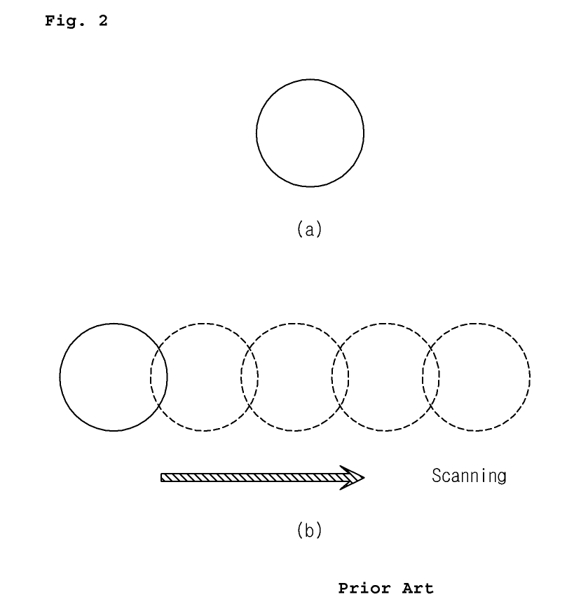

### DETAILED DESCRIPTION

Hereinafter, a scanning electron microscope capable of controlling the spot of an electron beam in accordance with an embodiment of the present invention is described in detail with reference to the accompanying drawings.

The scanning electron microscope capable of controlling the spot of an electron beam in accordance with an embodiment of the present invention is configured to include an electromagnetic lens, including an electron gun for outputting an electron beam and an electron coil, and a pair of stigmators and to control a path in which the spot of the electron beam reaches a sample. The scanning electron microscope further includes electron magnets disposed on the side opposite the side in which the spot of an electron beam is controlled by the pair of stigmators and configured to control (or correct) the shape of a spot in a desired shape. The electron magnets are provided within an electron beam that moves from the electron beam source of the scanning electron microscope to a sample in order to control the spot of the electron beam irradiated to the sample so that it becomes a linear electron beam in which a horizontal to vertical ratio is different. When the electron beam is output by the electron beam source, a control unit controls the ratio and direction of the spot of the electron beam by controlling the supply voltage of the electron magnets.

In the scanning electron microscope capable of controlling the spot of an electron beam and a measurement method using the same in accordance with embodiments of the present invention, an existing two-dimensional beam is irradiated and scanned in one dimension (i.e., a linear form) by freely controlling the shape of an electron beam output by the scanning electron microscope.

Unlike in a conventional scanning electron microscope, edge accuracy and a fast scanning speed in a specific direction can be achieved by performing scanning only in a desired direction using an extremely astigmatic electron beam spot not a stigmatic electron beam spot.

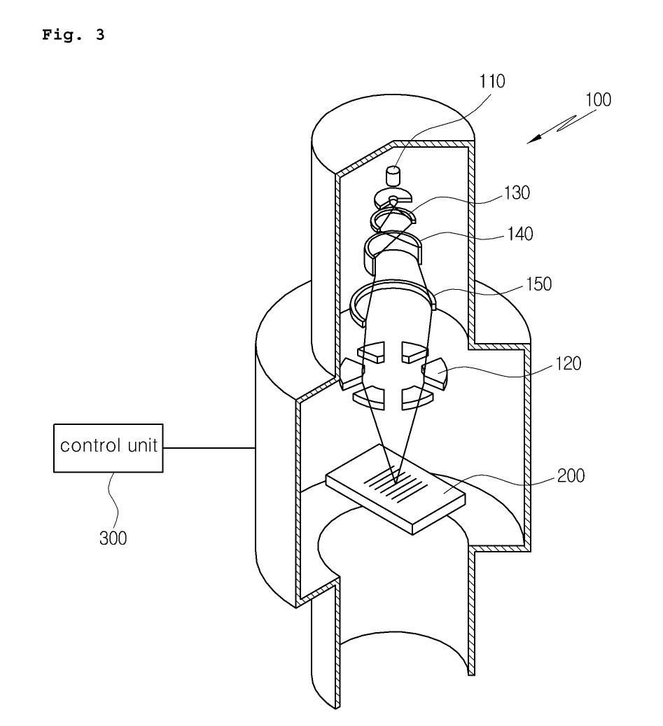

FIG. 3 illustrates the configuration of a scanning electron microscope capable of controlling the spot of an electron beam in accordance with an embodiment of the present invention. As schematically illustrated in FIG. 3, the scanning electron microscope 100 may be configured to include an electron beam source 110, a plurality of optical systems 130 to 150 configured to control a path in which an electron beam output by the electron beam source moves, electron magnets 120 configured to control the shape of the electron beam according to the gist of the present invention, and a control unit 300 configured to control the electron magnets within a vacuum body (not reference numeral assigned).

More specifically, the scanning electron microscope is configured to include an electromagnetic lens, including an electron gun for outputting an electron beam and an electron coil, and a pair of stigmators and to control a path in which the spot of an electron beam reaches a sample 200. The scanning electron microscope further includes the electron magnets disposed on the side opposite the side in which the spot of an electron beam is controlled by the pair of stigmators and configured to control (or correct) the spot in a desired shape.

In an embodiment of the present invention, the configuration of the scanning electron microscope has been illustrated in FIG. 3, but a detailed configuration of the scanning electron microscope may changed in various ways as known in the art. In an embodiment of the present invention, the scanning electron microscope is configured to include the electron magnets for controlling an optical image in order to irradiate an output electron beam in the form of an extremely astigmatic electron beam spot.

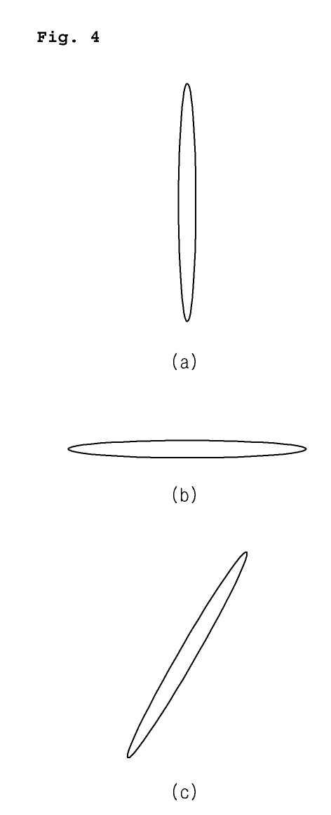

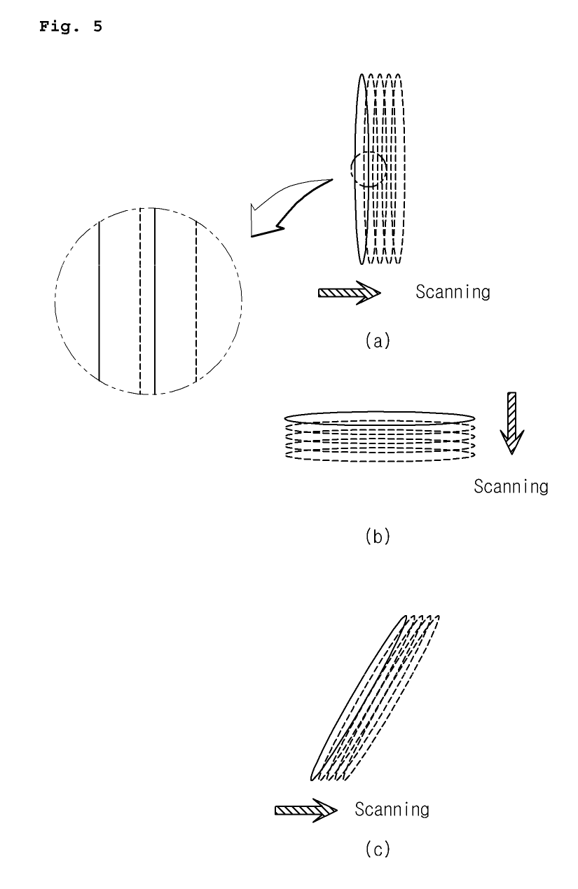

FIG. 4 is a diagram illustrating the shapes of electron beams formed by the scanning electron microscope capable of controlling the spot of an electron beam in accordance with an embodiment of the present invention, and FIG. 5 is a diagram consecutively illustrating the scanning states of electron beams through the scanning electron microscope in accordance with an embodiment of the present invention. An astigmatic state has an effect in that the focus of an image leans to one side. In this case, resolution can be increased because an edge is detected more sharply in a direction in which the focus is inclined.

Furthermore, in order to scan an image in one direction, the thickness of the spot of an electron beam in a direction opposite the direction of the scan direction is controlled so that it is almost close to 0 (zero). The length of the spot of the electron beam is relatively increased with respect to the scan direction. In this case, an averaging effect of the image corresponding to the increased length can be expected, and a scanning speed is increased.

Accordingly, the averaging effect can be further maximized by increasing the number of frames for a specific speed. For example, scanning may be performed in a diagonal line or at a desired angle as well as x and y directions using the method described above.

More specifically, in astigmatic control, astigmatism and the distortion of an image are frequently generated in a scanning electron microscope. The reason for this is that the pixel of a CRT is round, whereas the spot of an electron beam incident on a sample or the spot of a secondary electron emitted from a sample are not precisely round. Astigmatism is generated when an elliptical spot incident on a sample is to be matched with the circular pixel of a CRT. This is the greatest cause of limiting the resolution of a scanning electron microscope. A pair of stigmators is mounted on all the scanning electron microscopes. The reason for this is to correct the shape of a distorted spot by applying a magnetic field to the opposite side.

Furthermore, an embodiment of the present invention includes all the spot sizes of an electron beam that is first determined in control of the spot of the electron beam using the electron magnets. For example, an embodiment of the present invention includes controlling the size of the spot of an electron beam using the electron magnets when the size of the spot is 2.0 nm in a normal state and controlling the size of the spot of an electron beam using the electron magnets when the size of the spot is less than 2.0 nm or 2.0 nm or more.

As described above, in an embodiment of the present invention, edge accuracy and fast test scanning in a specific direction can be realized using an astigmatic electron beam spot not an electron beam spot of a two-dimensional (or circular) shape.

The scanning electron microscope configured and driven as described above in accordance with an embodiment of the present invention is advantageous in that high-speed scanning and measurement with higher precision and higher accuracy are possible because an extended electron beam is irradiated to a subject to be tested.

Furthermore, the scanning electron microscope in accordance with an embodiment of the present invention is advantageous in that it is flexible depending on a characteristic of a subject to be tested because the diversity of a measurement method can be secured by irradiating the spot of an electron beam in a diagonal direction not in an x or y axis direction when performing scanning.

As described above, although the exemplary embodiments of the present invention have been described in order to illustrate the principle of the present invention, the present invention is not limited to the aforementioned configuration and operation. Those skilled in the art will appreciate that the present invention may be changed and modified in various ways without departing from the spirit and scope of the present invention. Accordingly, all proper changes and modifications and equivalents thereof should be construed as belonging to the scope of the present invention.

1. A scanning electron microscope (SEM), comprising:
electron magnets disposed in a path in which an electron beam irradiated to a sample moves from an electron beam source of the scanning electron microscope to a sample and configured to control and irradiate a spot of the electron beam in a linear electron beam having a different horizontal to vertical ratio; and
a control unit to control a ratio and direction of the spot of the electron beam by controlling a supply voltage of the electron magnets.

2. The scanning electron microscope of claim 1, wherein the control unit extends the electron beam in a vertical axis or a horizontal axis by controlling a direction and size of electromagnetic force of the electron magnets.

3. The scanning electron microscope of claim 1, wherein the control unit extends the electron beam in a diagonal direction so that the electron beam has a specific angle by controlling a direction and size of electromagnetic force of the electron magnets.

4. The scanning electron microscope of claim 1, wherein:
the electron beam comprises all spot sizes of an electron beam that is first determined in controlling the spot of the electron beam using the electron magnets, and
controlling the spot of the electron beam comprises controlling the spot of the electron beam using the electron magnets when the size of the spot is 2.0 nm in a normal state and controlling the spot of the electron beam using the electron magnets when the size of the spot is less than 2.0 nm or 2.0 nm or more.

5. A measurement method using a scanning electron microscope comprising electron magnets disposed in a path in which an electron beam irradiated to a sample moves from an electron beam source of the scanning electron microscope to a sample and configured to control and irradiate a spot of the electron beam in a linear electron beam having a different horizontal to vertical ratio, the measurement method comprising the steps of:
consecutively irradiating and scanning, by a control unit, a linear electron beam by controlling a supply voltage of the electron magnets when the electron beam is output by the electron beam source.

6. The measurement method of claim 5, further comprising the step of extending the electron beam in a vertical axis or a horizontal axis by controlling a direction and size of electromagnetic force of the electron magnets.

7. The measurement method of claim 5, further comprising the step of extending the electron beam in a diagonal direction so that the electron beam has a specific angle by controlling a direction and size of electromagnetic force of the electron magnets.

8. The measurement method of claim 5, wherein:
the electron beam comprises all spot sizes of an electron beam that is first determined in controlling a spot of the electron beam using the electron magnets, and
controlling the spot of the electron beam comprises controlling the spot of the electron beam using the electron magnets when the size of the spot is 2.0 nm in a normal state and controlling the spot of the electron beam using the electron magnets when the size of the spot is less than 2.0 nm or 2.0 nm or more.

9. A scanning electron microscope configured to control a path in which a spot of an electron beam reaches a sample, the scanning electron microscope comprising:
an electromagnetic lens comprising an electron gun for outputting an electron beam and an electron coil;
a pair of stigmators;
electron magnets placed on a side opposite a side in which the spot of the electron beam is controlled by the pair of stigmators and configured to control or correct the spot in a desired shape;
wherein the electron magnets are disposed in a path in which the electron beam irradiated to a sample moves from an electron beam source of the scanning electron microscope to a sample and configured to control and irradiate the spot of the electron beam in a linear electron beam having a different horizontal to vertical ratio; and
a control unit to control a ratio and direction of the spot of the electron beam by controlling a supply voltage of the electron magnets.

10. The scanning electron microscope of claim 9, wherein:
the electron beam comprises all spot sizes of an electron beam that is first determined in controlling the spot of the electron beam using the electron magnets, and
controlling the spot of the electron beam comprises controlling the spot of the electron beam using the electron magnets when the size of the spot is 2.0 nm in a normal state and controlling the spot of the electron beam using the electron magnets when the size of the spot is less than 2.0 nm or 2.0 nm or more.
